(19) United States
(12) Patent Application Publication
(10) Pub. No.: US 2026/0190621 A1
(43) Pub. Date: Jul. 2, 2026

(54) Display Substrate, Display Panel, and Display Method Therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Chenghao LIAO, Beijing (CN); Lu ZHANG, Beijing (CN); Yiyang ZHANG, Beijing (CN); Yuqian HE, Beijing (CN); Guoqiang WU, Beijing (CN); Shuai HOU, Beijing (CN)

(21) Appl. No.: 18/866,085

(22) PCT Filed: Aug. 12, 2024
(86) PCT No.: PCT/CN2024/111483

§ 371 Date: Nov. 15, 2024

(30) Foreign Application Priority Data
Sep. 26, 2023 (CN) 202311257304.1

(51) Int. Cl. H10K 59/121; H10K 50/19; H10K 59/35; H10K 59/86

(52) U.S. Cl. CPC H10K 59/1213; H10K 50/19; H10K 59/1216; H10K 59/353; H10K 59/86

(57) ABSTRACT

A display substrate, a display panel, and a display apparatus are provided, The display substrate of the present disclosure includes a base substrate and multiple pixel structures on the base substrate. Each pixel structure includes a pixel drive circuit and at least two light emitting devices, the pixel drive circuit includes at least two drive sub-circuits, one drive sub-circuit is electrically connected to a first electrode of one of the light emitting devices, and multiple light emitting devices are stacked on the base substrate. The multiple pixel structures on the display substrate are arranged in a honeycomb structure. The display substrate of the present disclosure can be selectively driven, all the light emitting devices being driven to emit light in a high brightness mode, and a single layer light emitting device being driven to emit light in the low brightness mode,

### CROSS-REFERENCE TO RELATED APPLICATIONS

The present application is a U.S. National Phase Entry of International Application PCT/CN2024/111483 having an international filing date of Aug. 12, 2024, which claims priority to Chinese patent application No. 202311257304.1, filed with the CNIPA on Sep. 26, 2023, which are hereby incorporated herein by reference in their entireties.

### TECHNICAL FIELD

The present disclosure pertains to a technical field of display product control, and particularly relates to a display substrate, a display panel, and a display method therefor, and a display apparatus.

### BACKGROUND

With the continuous development of display technology, besides achieving higher display quality, there are also higher requirements on other aspects of a display substrate, one of which is to improve current efficiency and reduce display power consumption. In order to improve the display effect and service life of the existing display substrate, two active-matrix organic light emitting diode (AMOLED) devices are usually used as two layers of display screens, but the two layers of display screens cannot work alone, which makes the display substrate have great power consumption.

Based on the above problems, the inventors propose a novel display substrate based on two-layer AMOLED devices, which can realize dynamic switching of single-layer display and double-layer display, and in a high brightness mode, two layers of light emitting devices jointly emit light, and in a low brightness mode, a single layer of light emitting devices emit light, which effectively reduces the power consumption of the display substrate and improves the service life of the light emitting devices on the premise of ensuring the display effect.

### SUMMARY

The present disclosure aims at solving at least one of technical problems existing in the prior art, and provides a display substrate, a display panel and a display method for the display panel, and a display apparatus.

According to a first aspect, an embodiment of the present disclosure provides a display substrate including: a base substrate and a plurality of pixel structures on the base substrate, a pixel structure including a pixel drive circuit and at least two light emitting devices; wherein, for one of the pixel structures, the pixel drive circuit includes at least two drive sub-circuits, one of the drive sub-circuits is electrically connected to a first electrode of one of the light emitting devices; wherein the at least two light emitting devices are sequentially stacked in a direction away from the base substrate, and are connected in series.

Optionally, for two adjacently disposed light emitting devices in one of the pixel structures, a second electrode of one of the two adjacently disposed light emitting devices relatively close to the base substrate is also used as a first electrode of one of the two adjacently disposed light emitting devices relatively away from the base substrate.

Optionally, the pixel structure includes two light emitting devices which include a first light emitting device and a second light emitting device, respectively, and the first light emitting device is closer to the base substrate than the second light emitting device, and the pixel drive circuit includes two drive sub-circuits which include a first drive sub-circuit and a second drive sub-circuit, respectively;
wherein the first drive sub-circuit is configured to control the first light emitting device and the second light emitting device to emit light by a first power supply voltage in response to a first control signal; and
the second drive sub-circuit is configured to control the second light emitting device to emit light by a second power supply voltage in response to a second control signal.

Optionally, the pixel drive circuit further includes a first switch sub-circuit and a second switch sub-circuit;
the first switch sub-circuit is configured to turn on a connection of the first drive sub-circuit with a first electrode of the first light emitting device or turn on a connection of the second drive sub-circuit with a first electrode of the second light emitting device, in response to a third control signal; and
the second switch sub-circuit is configured to output a source drive signal as the first control signal or output the source drive signal as the second control signal, in response to the third control signal.

Optionally, the first switch sub-circuit includes a third transistor and a fourth transistor;
a control electrode of the third transistor is connected to a third control signal terminal, a first electrode of the third transistor is connected to the first electrode of the first light emitting device, and a second electrode of the third transistor is connected to the first drive sub-circuit; and
a control electrode of the fourth transistor is connected to the third control signal terminal, a first electrode of the fourth transistor is connected to the first electrode of the second light emitting device, and a second electrode of the fourth transistor is connected to the second drive sub-circuit.

Optionally the second switch sub-circuit includes a fifth transistor and a sixth transistor;
a control electrode of the fifth transistor is connected to a third control signal terminal, a first electrode of the fifth transistor is connected to a first control signal terminal, and a second electrode of the fifth transistor is connected to a source drive signal terminal; and
a control electrode of the sixth transistor is connected to the third control signal terminal, a first electrode of the sixth transistor is connected to a second control signal terminal, and a second electrode of the sixth transistor is connected to the source drive signal terminal.

Optionally, the first drive sub-circuit includes a first transistor and a first storage capacitor;
a control electrode of the first transistor is connected to a first control signal terminal, a first electrode of the first transistor is connected to a first electrode of the first light emitting device, and a second electrode of the first transistor is connected to a first level signal terminal; and
one electrode of the first storage capacitor is connected to the control electrode of the first transistor, and the other electrode of the first storage capacitor is connected to the second electrode of the first transistor, to control a working time of the first transistor.

Optionally, the second drive sub-circuit includes a second transistor and a second storage capacitor;
a control electrode of the second transistor is connected to a second control signal terminal, a first electrode of the second transistor is connected to a first terminal of the second light emitting device, and a second electrode of the second transistor is connected to a second level signal terminal; and
one electrode of the second storage capacitor is connected to the control electrode of the first transistor, and the other electrode of the second storage capacitor is connected to the second electrode of the second transistor, to control a working time length of the second transistor.

Optionally, the pixel structures in the display substrate in the display substrate are divided into a first pixel group and a second pixel group alternately disposed in a first direction and a third pixel group and a fourth pixel group alternately disposed in a second direction;
the first pixel group includes pixel structures of a first color and pixel structures of a second color alternately disposed in the second direction;
the second pixel group includes pixel structures of a third color disposed side by side in the second direction;
the third pixel group includes pixel structures of the first color and pixel structures of the second color alternately disposed in the first direction; and
the fourth pixel group includes pixel structures of the third color disposed side by side in the first direction.

Optionally, the pixel structure includes two light emitting devices which include a first light emitting device and a second light emitting device, respectively, and the first light emitting device is closer to the base substrate than the second light emitting device;
for one of the pixel structures, an orthographic projection of a light emitting layer of the second light emitting device on the base substrate covers an orthographic projection of a light emitting layer of the first light emitting device on the base substrate.

Optionally, a profile of the orthographic projection of the light emitting layer of the second light emitting device on the base substrate is hexagonal, and a profile of the orthographic projection of the light emitting layer of the first light emitting device on the base substrate is rectangular.

In a second aspect, the present disclosure provides a display panel including the above-described display substrate.

In a third aspect, the present disclosure provides a display method for the display panel, including:
for one of the pixel structures, controlling a drive sub-circuit in a pixel drive circuit to operate to control one or more of the light emitting devices to emit light.

Optionally, the pixel structure includes two light emitting devices which include a first light emitting device and a second light emitting device, respectively, and the first light emitting device is closer to the base substrate than the second light emitting device, and the pixel drive circuit includes two drive sub-circuits which include a first drive sub-circuit and a second drive sub-circuit, respectively; the method includes:
writing a second control signal into the second drive sub-circuit, and writing a second level signal into a first electrode of the second light emitting device, to drive the second light emitting device to emit light;
writing a first control signal into the first drive sub-circuit, and writing a first level signal into a first electrode of the first light emitting device and the first electrode of the second light emitting device, to drive the first light emitting device and the second light emitting device to emit light together.

Optionally, the pixel structure includes two light emitting devices which include a first light emitting device and a second light emitting device, respectively, and the first light emitting device is closer to the base substrate than the second light emitting device, and the pixel drive circuit includes two drive sub-circuits which include a first drive sub-circuit and a second drive sub-circuit, respectively; the pixel drive circuit further includes a first switch sub-circuit and a second switch sub-circuit; the method includes:
writing a third control signal into the first switch sub-circuit and the second switch sub-circuit, turning on a sixth transistor and a fourth transistor, writing a second control signal into a second transistor, and writing a second level signal into a first electrode of the second light emitting device, to drive the second light emitting device to emit light;
writing the third control signal into the first switch sub-circuit and the second switch sub-circuit, turning on a fifth transistor and a third transistor, writing a first control signal into the first transistor, and writing a first level signal into a first electrode of the first light emitting device and the first electrode of the second light emitting device, to drive the first light emitting device and the second light emitting device to emit light together.

Optionally, the pixel structures in the display substrate in the display substrate are divided into a first pixel group and a second pixel group alternately disposed in a first direction and a third pixel group and a fourth pixel group alternately disposed in a second direction; the first pixel group includes pixel structures of a first color and pixel structures of a second color alternately disposed in the second direction; the second pixel group includes pixel structures of a third color disposed side by side in the second direction; the third pixel group includes pixel structures of the first color and pixel structures of the second color alternately disposed in the first direction; the fourth pixel group includes pixel structures of the third color disposed side by side in the first direction; the method includes:
determining a luminous brightness value of a pixel structure of a first color, a luminous brightness value of a pixel structure of a second color, and a luminous brightness value of a pixel structure of a third color in each virtual pixel unit according to a picture to be displayed;
controlling the pixel structure of the first color, the pixel structure of the second color, and the pixel structure of the third color to emit light according to the determined luminous brightness value of the pixel structure of the first color, the determined luminous brightness value of the pixel structure of the second color, and the determined luminous brightness value of the pixel structure of the third color in each virtual pixel unit;
wherein a luminous brightness of the pixel structure of the third color in each virtual pixel unit is realized by sharing luminous brightnesses of eight pixel structures of the third color nearest thereto; a luminous brightness of each pixel structure of the third color is realized by controlling luminous brightnesses of a first light emitting device and a second light emitting device in the pixel structure.

In third aspect, the present disclosure further provides a display apparatus, including the display panel described above.

### BRIEF DESCRIPTION OF DRAWINGS

FIG. 1 is a schematic diagram of a structure of a display substrate including a pixel structure according to an embodiment of the present disclosure.

FIG. 2 is an equivalent circuit diagram of the display substrate of FIG. 1 according to the present disclosure.

FIG. 3 is a schematic diagram of a structure of a display substrate including two-pixel structures according to an embodiment of the present disclosure.

FIG. 4 is an optimization scheme of the equivalent circuit diagram of the display substrate shown in FIG. 2 according to the present disclosure.

FIG. 5 is an arrangement method of a plurality of pixel structures according to the present disclosure.

FIG. 6 is a schematic diagram of a structure of nine green pixel structures arranged in a 3 * 3 array according to the present disclosure.

FIG. 7 is a display method for the display substrate of FIG. 6 according to the present disclosure.

### DETAILED DESCRIPTION

To enable those skilled in the art to better understand the technical solutions of the present disclosure, a further detailed description of the present disclosure is given below with reference to the accompanying drawings and detailed description.

Unless otherwise defined, technical terms or scientific terms used in the present disclosure should have the meanings as commonly understood by those of ordinary skills in the art that the present disclosure pertains to. Terms “first”, “second” and similar terms used in the present disclosure do not indicate any order, quantity, or importance, but are used only for distinguishing different components. Similarly, similar wordings such as “a”, “an” or “the” do not denote a limitation on quantity, but rather denote the presence of at least one. “Include”, “contain”, or similar words mean that elements or objects appearing before the wordings cover elements or objects listed after the wordings and their equivalents, but do not exclude other elements or objects. “Connect”, “couple”, or similar wordings are not limited to a physical or mechanical connection, but may include an electrical connection, whether direct or indirect. “Upper”, “lower”, “left”, and “right”, etc., are used for representing a relative positional relationship, and when an absolute position of a described object is changed, the relative positional relationship may also be correspondingly changed.

It should be noted here that a transistor used in embodiments of the present disclosure may be a thin film transistor, a field effect transistor, or a same device with other characteristics. Since a source electrode and a drain electrode of the transistor used are symmetrical, there is no difference between the source electrode and the drain electrode of the transistor. In an embodiment of the present disclosure, in order to distinguish the source electrode and the drain electrode of the transistor, one of the two electrodes is referred to as a first electrode, the other is referred to as a second electrode, and a gate electrode is referred to as a control electrode. A light emitting device of the present disclosure may be equivalent to a light emitting diode, and in order to distinguish a positive electrode and a negative electrode of the light emitting diode, the positive electrode is referred to as a first electrode and the negative electrode is referred to as a second electrode. However, the positive electrode is the first electrode and the negative electrode is the second electrode, which do not constitute the protection scope of the present disclosure. In practical applications, relative positions of a drive sub-circuit and the light emitting device can be adjusted, which also fall within the protection scope of the present disclosure.

A conventional OLED light emitting device is composed of a hole transport layer, a light emitting layer and an electron transport layer, sandwiched between an anode electrode and a cathode electrode. Subsequently, in order to improve performance of OLED light emitting devices, multi-layer light emitting units were designed one after another, such as continuously adding organic functional layers including a hole injection layer, an electron injection layer, an electron block layer and a hole block layer. After that, a concept of light emitting unit doped OLED has also been proposed. By optimizing thicknesses of the organic functional layers, improving manufacturing process and applying each organic functional layer, light emitting performance of OLED light emitting devices has been steadily improved.

In order to further improve the performance of OLED light emitting devices, a concept of Tandem OLED came into being. A tandem OLED is an OLED in which multi-layer light emitting devices in a light emitting device are connected in series and is only controlled by an external power supply source. Under a same voltage, compared with a single-layer OLED light emitting device, a Tandem OLED light emitting device has higher luminous brightness and current efficiency. The luminous brightness and current efficiency increase exponentially with increase of a quantity of light emitting units in series, and lifetime of a Tandem OLED is longer than that of a single-layer OLED under a same current density. However, due to existence of multi-layer light emitting units in the Tandem OLED, compared with the single-layer OLED, a working voltage used is higher and there is a problem that a power efficiency is lower. Higher working voltage and lower power efficiency will affect power consumption of the Tandem OLED light emitting device adversely and reduce performance of the Tandem OLED light emitting device.

In view of this, an embodiment of the present disclosure provides a display substrate 100 based on the Tandem OLED light emitting device, and this display substrate 100 can realize dynamic selective driving. In the low brightness mode, a part of the OLED light emitting devices are driven to emit light separately to achieve lower brightness and more uniform display effects, while reducing display power consumption. In the high brightness mode, all OLED light emitting devices are driven to emit light together, which can greatly enhance the luminous brightness.

Hereinafter, a display substrate 100 according to an embodiment of the present disclosure will be described with reference to the drawings and specific embodiments.

An embodiment of the present disclosure provides a display substrate 100 including a base substrate 8 and a plurality of pixel structures located on the base substrate 8, and the pixel structures include a red pixel structure, a blue pixel structure, and a green pixel structure. The plurality of pixel structures are arranged in a honeycomb structure, which can ensure that all pixel structures are evenly distributed and maximize a luminous area. Taking the green pixel structure as an example, the nine-pixel structure arranged in an array has a 3 * 3 nine-square grid color sharing mode, which can improve the display effect of the display panel and ensure clarity of pictures.

Herein, each pixel structure includes a pixel drive circuit and at least two light emitting devices. Each pixel drive circuit includes at least two drive sub-circuits, and one drive sub-circuit is electrically connected with a first electrode of one light emitting device. For two light emitting devices adjacently disposed in one pixel structure, a second electrode of one of the two light emitting devices relatively close to the base substrate 8 is also used as a first electrode of one of the two light emitting devices relatively remote from the base substrate 8. In order to facilitate understanding, in the present disclosure, the display substrate 100 and the drive mode thereof are described and illustrated by only taking an example that each pixel structure includes two drive sub-circuits and two light emitting devices.

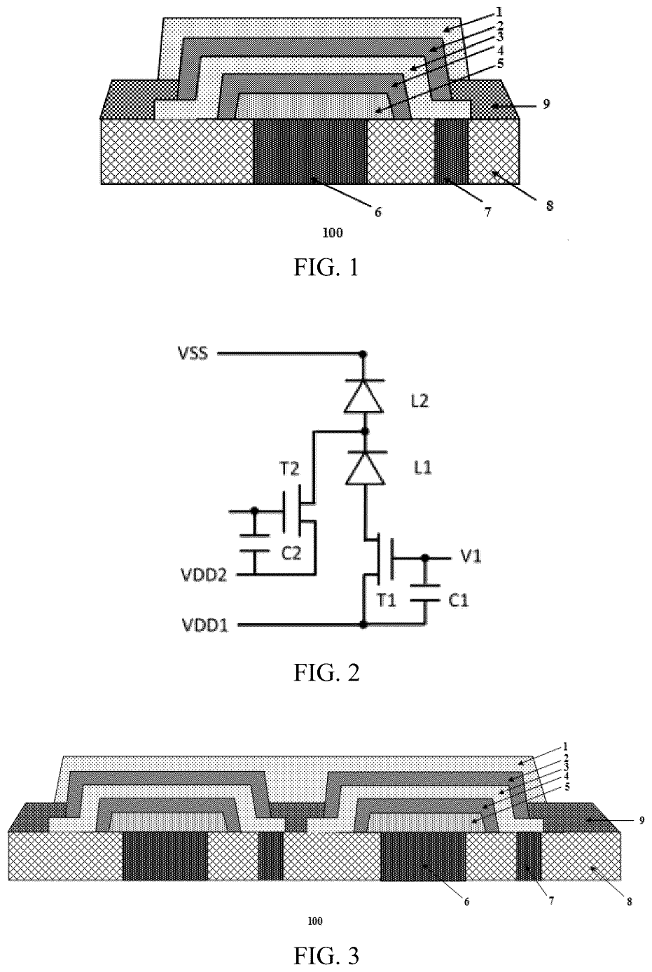

FIG. 1 is a schematic diagram of a structure of a display substrate 100 according to an embodiment of the present disclosure, and FIG. 2 is an equivalent control circuit diagram of the display substrate 100. Referring to FIGS. 1 and 2, the display substrate 100 has a first light emitting layer 4 and a second light emitting layer 2, which are corresponding to a first light emitting device L1 and a second light emitting device L2 in the equivalent circuit respectively. The first light emitting device L1 is closer to the display substrate 100 than the second light emitting device L2, and a second electrode of the first light emitting device L1 is also used as a second electrode of the second light emitting device L2. Referring to FIG. 1, the first light emitting layer 4 and the second light emitting layer 2 are connected in series through a second connection electrode 3, and the second connection electrode 3 is electrically connected to a second drive sub-circuit 7 to realize separate control of the second light emitting device L2, that is, to realize low brightness display by the display substrate 100. The first light emitting device L1 and a first drive sub-circuit 6 are electrically connected through a first connection electrode 5, that is, by sequentially electrically connecting the first drive sub-circuit 6 to the first light emitting layer 4 and the second light emitting layer 2, simultaneous control of the first light emitting layer 4 and the second light emitting layer 2 can be achieved, that is, a high brightness display of the display substrate 100 can be achieved.

Exemplarily, the display substrate 100 further includes a third connection electrode 1. Referring to FIGS. 1 and 2, when the display substrate 100 is operating, the third connection electrode 1 serves as a cathode trace and is connected to a low level signal, and the first drive sub-circuit 6 and the second drive sub-circuit 7 are electrically connected to high level signals. The high level signals to which the first drive sub-circuit 6 and the second drive sub-circuit 7 are connected may be different. Among them, for the display substrate 100 including the plurality of pixel structures, the third connection electrodes 1 of the plurality of pixel structures can be shared, and can be prepared by a one-time patterning process, to reduce process complexity, as shown in FIG. 3.

Optionally, the second connection electrode 3 and the third connection electrode 1 are both transparent electrodes, which can ensure a light transmittance of the display substrate 100. The first connection electrode 5 may include a transparent electrode or a non-transparent metal electrode. Because the first connection electrode 5 is only used to be connected to the first drive sub-circuit 6 and the first light emitting layer 4, the light transmittance of the display substrate 100 will not be affected. At present, materials used for manufacturing the transparent electrode mainly include indium tin oxide (ITO) and indium zinc oxide (IZO) which both have excellent conductivity and transparency, and can conduct current without affecting luminous brightness. However, the manufacturing process of the transparent electrode is relatively complex. Compared with the transparent electrode, a metal electrode is simpler to manufacture and lower in cost.

As another example, the display substrate 100 further includes an insulation layer 9 for isolating adjacent pixel structures to avoid leakage of electricity or signal crosstalk. A material of the insulation layer 9 may include silicon oxide, silicon nitride, or rubber, or the like.

Optionally, the light emitting devices in the above-described display panel may be equivalent to light emitting diodes, which have positive and negative electrodes. In the embodiment of the present disclosure, it is described by only taking an example in which the third connection electrode 1 is connected to a negative electrode of a light emitting device, but the third connection electrode 1 being connected to the negative electrode of the light emitting device is defined as in the scope of protection of the present disclosure.

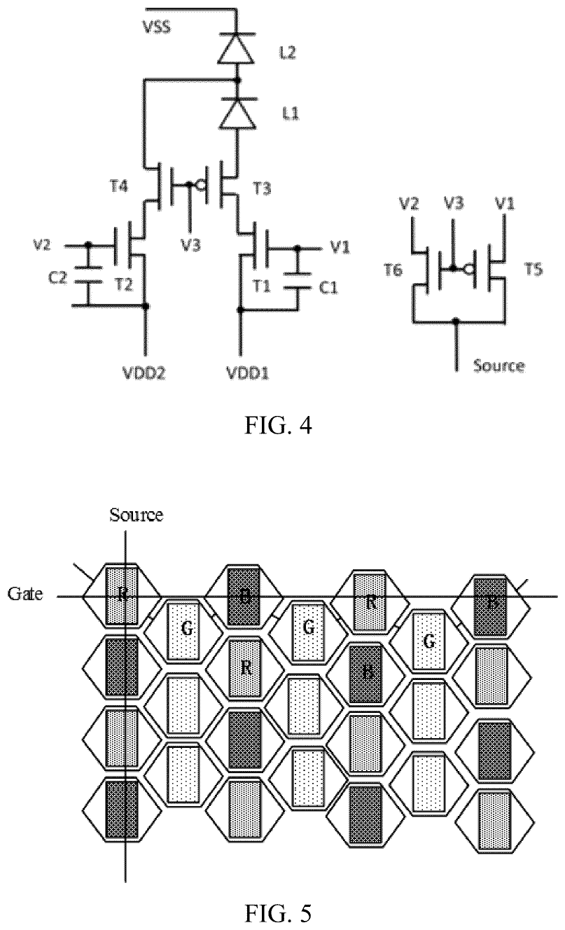

Optionally, FIG. 4 is an optimized circuit of the equivalent circuit diagram in FIG. 2 according to the present disclosure. Referring to FIG. 2, a first pixel circuit includes a first transistor T1, a gate electrode of the first transistor T1 is connected to a first control signal V1 and is turned on or off under control of the first control signal V1, and a first level signal VDD1 is transmitted to a first electrode of a first light emitting device L1. It takes a certain time for the first transistor T1 to go from a turned-on state to a steady state, and similarly, it takes a certain time for the first transistor T1 to go from the steady state to a turned-off state, resulting in deterioration in switching characteristics of the first transistor T1. Therefore, an optimized control circuit diagram in FIG. 4 is proposed, in which a first switch sub-circuit and a second switch sub-circuit are added compared with the control circuit in FIG. 2, and high brightness mode and low brightness mode of the display substrate 100 can be realized by controlling a third control signal V3.

Continuing to refer to FIG. 4, the equivalent circuit in the present embodiment includes the first light emitting device L1, a second light emitting device L2, the first transistor T1, a second transistor T2, a third transistor T3, a fourth transistor T4, a fifth transistor T5, and a sixth transistor T6. The first transistor T1, the second transistor T2, the fourth transistor T4, and the sixth transistor T6 are all N-type transistors, and the third transistor T3 and the fifth transistor T5 are P-type transistors. A second electrode of the first light emitting device L1 is electrically connected to a first electrode of the second light emitting device L2, and a second electrode of the second light emitting device L2 is electrically connected to a third level signal terminal. The gate electrode of the first transistor T1 is connected to a first control signal terminal, the first electrode of the first transistor T1 is connected to a second electrode of the third transistor T3, and a second electrode of the first transistor T1 is connected to a first level signal terminal. A gate electrode of the second transistor T2 is connected to a second control signal terminal, a first electrode of the second transistor T2 is connected to a second electrode of the fourth transistor T4, and a second electrode of the second transistor T2 is connected to a second level signal terminal. A gate electrode of the third transistor T3 is connected to a third signal input terminal, a first electrode of the third transistor T3 is connected to a first electrode of the first light emitting device L1, and the second electrode of the third transistor T3 is connected to the first electrode of the first transistor T1. A gate electrode of the fourth transistor T4 is connected to a third control signal terminal, a first electrode of the fourth transistor T4 is connected to the first electrode of the second light emitting device L2, and the second electrode of the fourth transistor T4 is connected to the first electrode of the second transistor T2. A gate electrode of the fifth transistor T5 is connected to the third control signal terminal, a first electrode of the fifth transistor T5 is connected to the first control signal terminal, and a second electrode of the fifth transistor T5 is connected to a source drive signal terminal Source. A gate electrode of the sixth transistor T6 is connected to a third signal input terminal, a first electrode of the sixth transistor T6 is connected to a second signal input terminal, and a second electrode of the sixth transistor T6 is connected to the source drive signal terminal Source.

Optionally, the control circuit further includes a first storage capacitor C1 and a second storage capacitor C2. The first storage capacitor C1 is electrically connected to the gate electrode and the source electrode of the first transistor T1, and a discharging or charging speed of the first storage capacitor C1 can be controlled by adjusting a magnitude of the first storage capacitor C1 and a voltage across the two electrodes, thereby controlling a working time length of the first transistor T1 and adjusting a time length during which the first light emitting device L1 and the second light emitting device L2 jointly emit light. The second storage capacitor C2 is electrically connected to the gate electrode and the source electrode of the second transistor T2, and a discharging or charging speed of the second storage capacitor C2 can be controlled by adjusting a magnitude of the second storage capacitor C2 and a voltage across the two electrodes, thereby controlling a working time length of the second transistor T2 and adjusting a time length during which the second light emitting device L2 emits light alone.

When a fifth level signal is input to the third signal input terminal, the third transistor T3 and the fifth transistor T5 are turned on, the first light emitting device LI and the second light emitting device L2 are both turned on, and the two layers emit light simultaneously, that is, the high brightness mode of the display substrate 100. When a fourth level signal is input to the third control signal V3, the fourth transistor T4 and the sixth transistor T6 are turned on, and the second light emitting device L2 emits light alone, that is, the low brightness mode of the display substrate 100.

It will be understood by those skilled in the art that a magnitude of a drive voltage provided by a drive power supply source may be at least equal to a drive voltage at a maximum brightness of a light emitting device connected to the drive power supply source. Since drive voltages at maximum brightness of light emitting devices of different colors are different, in this embodiment, pixel structures of different colors are connected to different drive power supply sources, at this time, the drive power supply sources can be selected to provide corresponding drive voltages for the pixel structures according to the colors of the pixel structures, and then the voltages distributed to drive transistors in each pixel structure can be reduced, so that power consumption of the drive transistors can be reduced, and of course, at this time, an overall power consumption of the pixel unit drive circuit is also reduced.

Exemplarily, the present disclosure further provides an arrangement of pixel structures on the display substrate 100, and a pixel structure include a pixel structure of a first color, a pixel structure of a second color, and a pixel structure of a third color. In the present disclosure, the first color is red, the second color is blue, and the third color is green, as an example for explanation. However, the first color being red, the second color being blue, and the third color being green do not define the scope of protection of the present disclosure. Herein, red pixel structures and blue pixel structures alternately arranged in a second direction constitute a first pixel group, green pixel structures arranged side by side in the second direction constitute a second pixel group, red pixel structures and blue pixel structures alternately arranged in a first direction constitute a third pixel group, and green pixel structures arranged side by side in the first direction constitute a fourth pixel group. Referring to FIG. 5, the pixel structures are arranged in a honeycomb structure. In the conventional pixel arrangement mode, each pixel includes three RGB pixel structures, that is, one red pixel structure, one blue pixel structure, and one green pixel structure are arranged together as one pixel, and a plurality of pixels are arranged in an array to form a display screen. This arrangement mode is simple, but because service lives of light emitting devices of the three color pixels are different (a service life of a blue light emitting device is shorter), a serious screen burn-in phenomenon will be generated, and a utilization rate of pixels is also very low. However, one pixel in the present disclosure includes four pixel structures RGBG, two groups of adjacent pixels will share one blue pixel structure or red pixel structure, human eyes are most sensitive to the green pixel structures, and the display substrate 100 of the present disclosure has a complete array arrangement of the green pixel structures, so delicacy and clarity of the picture can be improved, and at the same time, this arrangement can effectively increase a pixel density and improve the utilization rate of the pixels. However, in the embodiment of the present disclosure, orthographic projections of the three types of pixel structures on the base substrate may have a regular shape such as a square or a regular hexagon, or may have an irregular shape, which is not limited thereto.

In a second aspect, the present disclosure provides a display panel and a display method for the display panel, the display panel includes the display substrate 100 according to any one of the aforementioned embodiments and an opposing substrate disposed opposite to the display substrate 100. In an embodiment of the present disclosure, the display substrate 100 may be a color film substrate, and the opposing substrate may be an array substrate. Or, the display substrate 100 is a Color Filter on Array (COA) substrate, and the opposing substrate is an aligned substrate or an encapsulation cover.

Further, taking a display panel including one pixel structure as an example, the pixel structure includes two light emitting devices, namely, a first light emitting device L1 and a second light emitting device L2, respectively. The first light emitting device L1 is closer to the base substrate 8 than the second light emitting device L2, and the pixel drive circuit includes a first drive sub-circuit 6 and a second drive sub-circuit 7. The drive method includes: writing a second control signal V2 into the second drive sub-circuit 7, turning on the second transistor T2, transmitting the second level signal VDD2 to the first electrode of the second light emitting device L2, and driving the second light emitting device L2 to emit light alone, that is, the low brightness mode of the display panel; writing a first control signal V1 into the first drive sub-circuit 6, tuning on the first transistor T1, transmitting the first level signal VDD1 to the second electrode of the first light emitting device L1, and driving the first light emitting device L1 and the second light emitting device L2 to emit light together, that is, the high brightness mode of the display panel.

In some examples, the pixel drive circuit further includes a first switch sub-circuit and a second switch sub-circuit. At this time, the drive method includes: writing a third control signal into the first switch sub-circuit and the second switch sub-circuit, turning on the fourth transistor T4 and the sixth transistor T6, writing the second control signal V2 into the second transistor T2, controlling the second transistor T2 to be turned on, thereby writing the second level signal VDD2 into the first electrode of the second light emitting device L2, driving the second light emitting device L2 to emit light, i.e., the low brightness mode of the display panel; writing the third control signal V3 into the first switch sub-circuit and the second switch sub-circuit, turning on the third transistor T3 and the sixth transistor T6, writing the first control signal V1 into the first transistor T1, controlling the first transistor T1 to be turned on, so that writing the first level signal VDD1 into the first electrode of the first light emitting device L1, driving the first light emitting device L1 and the second light emitting device L2 to emit light together, that is, the high brightness mode of the display panel.

In some examples, the display method for the display panel includes: determining a luminous brightness value of a pixel structure of a first color, a luminous brightness value of a pixel structure of a second color, and a luminous brightness value of a pixel structure of a third color in each virtual pixel unit according to a picture to be displayed; controlling the pixel structure of the first color, the pixel structure of the second color, and the pixel structure of the third color to emit light according to the determined luminous brightness value of the pixel structure of the first color, the determined luminous brightness value of the pixel structure of the second color, and the determined luminous brightness value of the pixel structure of the third color in each virtual pixel unit; wherein a luminous brightness of the pixel structure of the third color in each virtual pixel unit is realized by sharing luminous brightnesses of eight pixel structures of the third color nearest thereto; a luminous brightness of each pixel structure of the third color is realized by controlling luminous brightnesses of a first light emitting device and a second light emitting device therein.

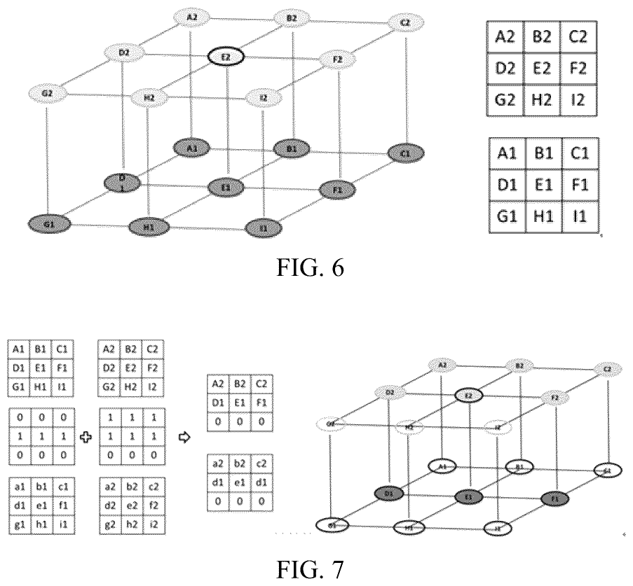

Further, taking the green pixel structure as an example, the nine pixel structures arranged in a 3*3 array realize a more uniform display effect of the light emitting device by the principle of color sharing. A pixel structure in the present disclosure has two light emitting layers, that is, each green pixel structure has two light emitting layers, the second light emitting layer 2 can emit light alone, the luminous brightness of the display substrate 100 at this time is the luminous brightness of the second light emitting layer 2. Moreover, the first light emitting layer 4 and the second light emitting layer 2 can emit light simultaneously, and the luminous brightness of the display substrate 100 at this time is a sum of luminous brightnesses of the first light emitting layer 4 and the second light emitting layer 2. As shown in FIG. 6, FIG. 6 shows a structure of nine pixels arranged in a 3*3 array, wherein luminance brightnesses of nine first light emitting layers 4 marking the structures of nine pixels are A₁˜I₁, weights of the nine first light emitting layers 4 are a₁˜i₁, luminance brightnesses of nine second light emitting layers 2 are A₂˜I₂, and weights of the nine second light emitting layers 2 are a₂˜i₂, wherein a luminance brightness of each light emitting layer depends on a magnitude of the third control signal V3, and when the luminance brightness value is 0, it means that the light emitting layer does not emit light. A weighted luminance brightness of each first light emitting layer 4 is a ratio of a sum of products of luminance brightnesses of all first light emitting layers 4 and their weights to a sum of weights of all light emitting layers whose luminance brightness are not 0, a weighted luminance brightness of each second light emitting layer 2 is a ratio of a sum of products of luminance brightnesses of all second light emitting layers 2 and their weights to a sum of weights of all light emitting layers whose luminance brightness are not 0, and a final weighted luminance brightness is a sum of weighted luminance brightnesses of the nine first light emitting layers 4 and weighted luminance brightnesses of the nine second light emitting layers 2, as shown in FIG. 7. By adopting the above hybrid light emitting mode, a low brightness display effect can be optimized, the brightness of the display substrate 100 can be further improved, and power consumption of the devices can be reduced, and service lives of the devices can be improved.

In a third aspect, an embodiment of the present disclosure further provides a display apparatus, including the display panel according to any one of the above embodiments. Of course, the display apparatus of the present embodiment may include other conventional structures, such as a power supply unit, a display drive unit, and the like. The display apparatus according to the embodiment of the present disclosure has great advantages when it is applied to products of small and medium-sized display panels, such as mobile phones, tablet computers, vehicle-mounted equipment, and wearable devices, and the like. Since laminated light emitting devices in the display panel can separately control light emission of different layers of light emitting devices compared with conventional light emitting devices, the power efficiency and current efficiency are improved, and the display effect of the laminated light emitting devices on the display panel can be better optimized, such as luminous brightness, color and other effects.

It is to be understood that the above embodiments are only exemplary embodiments employed for the purpose of illustrating the principles of the present disclosure, however, the present disclosure is not limited thereto. To those of ordinary skills in the art, various modifications and improvements may be made without departing from the essence and substance of the present disclosure, and these modifications and improvements are also considered to be within the scope of the present disclosure.

1. A display substrate comprising: a base substrate and a plurality of pixel structures on the base substrate, a pixel structure comprising a pixel drive circuit and at least two light emitting devices; wherein,
for one of the pixel structures, the pixel drive circuit comprises at least two drive sub-circuits, one of the drive sub-circuits is electrically connected to a first electrode of one of the light emitting devices; wherein the at least two light emitting devices are sequentially stacked in a direction away from the base substrate, and are connected in series.

2. The display substrate according to claim 1, wherein, for two adjacently disposed light emitting devices in one of the pixel structures, a second electrode of one of the two adjacently disposed light emitting devices relatively close to the base substrate is also used as a first electrode of one of the two adjacently disposed light emitting devices relatively away from the base substrate.

3. The display substrate according to claim 1, wherein the pixel structure comprises two light emitting devices which are a first light emitting device and a second light emitting device, respectively, and the first light emitting device is closer to the base substrate than the second light emitting device, and the pixel drive circuit comprises two drive sub-circuits which are a first drive sub-circuit and a second drive sub-circuit respectively; wherein,
the first drive sub-circuit is configured to control the first light emitting device and the second light emitting device to emit light by a first power supply voltage in response to a first control signal; and
the second drive sub-circuit is configured to control the second light emitting device to emit light by a second power supply voltage in response to a second control signal.

4. The display substrate according to claim 3, wherein the pixel drive circuit further comprises a first switch sub-circuit and a second switch sub-circuit;
the first switch sub-circuit is configured to turn on a connection of the first drive sub-circuit with a first electrode of the first light emitting device or turn on a connection of the second drive sub-circuit with a first electrode of the second light emitting device, in response to a third control signal; and
the second switch sub-circuit is configured to output a source drive signal as the first control signal or output the source drive signal as the second control signal, in response to the third control signal.

5. The display substrate according to claim 4, wherein the first switch sub-circuit comprises a third transistor and a fourth transistor;
a control electrode of the third transistor is connected to a third control signal terminal, a first electrode of the third transistor is connected to the first electrode of the first light emitting device, and a second electrode of the third transistor is connected to the first drive sub-circuit; and
a control electrode of the fourth transistor is connected to the third control signal terminal, a first electrode of the fourth transistor is connected to the first electrode of the second light emitting device, and a second electrode of the fourth transistor is connected to the second drive sub-circuit.

6. The display substrate according to claim 4, wherein the second switch sub-circuit comprises a fifth transistor and a sixth transistor;
a control electrode of the fifth transistor is connected to a third control signal terminal, a first electrode of the fifth transistor is connected to a first control signal terminal, and a second electrode of the fifth transistor is connected to a source drive signal terminal; and
a control electrode of the sixth transistor is connected to the third control signal terminal, a first electrode of the sixth transistor is connected to a second control signal terminal, and a second electrode of the sixth transistor is connected to the source drive signal terminal.

7. The display substrate according to claim 3, wherein the first drive sub-circuit comprises a first transistor and a first storage capacitor;
a control electrode of the first transistor is connected to a first control signal terminal, a first electrode of the first transistor is connected to a first electrode of the first light emitting device, and a second electrode of the first transistor is connected to a first level signal terminal; and
one electrode of the first storage capacitor is connected to the control electrode of the first transistor, and the other electrode of the first storage capacitor is connected to the second electrode of the first transistor, to control a working time length of the first transistor.

8. The display substrate according to claim 3, wherein the second drive sub-circuit comprises a second transistor and a second storage capacitor;
a control electrode of the second transistor is connected to a second control signal terminal, a first electrode of the second transistor is connected to a first terminal of the second light emitting device, and a second electrode of the second transistor is connected to a second level signal terminal; and
one electrode of the second storage capacitor is connected to the control electrode of the first transistor, and the other electrode of the second storage capacitor is connected to the second electrode of the second transistor, to control a working time length of the second transistor.

9. The display substrate according to claim 1, wherein the pixel structures in the display substrate are divided into a first pixel group and a second pixel group alternately disposed in a first direction and a third pixel group and a fourth pixel group alternately disposed in a second direction;
the first pixel group comprises pixel structures of a first color and pixel structures of a second color alternately disposed in the second direction;
the second pixel group comprises pixel structures of a third color disposed side by side in the second direction;
the third pixel group comprises pixel structures of the first color and pixel structures of the second color alternately disposed in the first direction; and
the fourth pixel group comprises pixel structures of the third color disposed side by side in the first direction.

10. The display substrate according to claim 1, wherein the pixel structure comprises two light emitting devices which are a first light emitting device and a second light emitting device respectively, and the first light emitting device is closer to the base substrate than the second light emitting device;
for one of the pixel structures, an orthographic projection of a light emitting layer of the second light emitting device on the base substrate covers an orthographic projection of a light emitting layer of the first light emitting device on the base substrate.

11. The display substrate according to claim 10, wherein a profile of the orthographic projection of the light emitting layer of the second light emitting device on the base substrate is hexagonal, and a profile of the orthographic projection of the light emitting layer of the first light emitting device on the base substrate is rectangular.

12. A display panel, comprising the base substrate according to claim 1.

13. A display method for the display panel according to claim 12, comprising:
for one of the pixel structures, controlling a drive sub-circuit in a pixel drive circuit to operate to control one or more of the light emitting devices to emit light.

14. The display method for the display panel according to claim 13, wherein the pixel structure comprises two light emitting devices which are a first light emitting device and a second light emitting device respectively, and the first light emitting device is closer to the base substrate than the second light emitting device, and the pixel drive circuit comprises two drive sub-circuits which are a first drive sub-circuit and a second drive sub-circuit respectively; the method comprises:
writing a second control signal into the second drive sub-circuit, and writing a second level signal into a first electrode of the second light emitting device, to drive the second light emitting device to emit light; and
writing a first control signal into the first drive sub-circuit, and writing a first level signal into a first electrode of the first light emitting device and the first electrode of the second light emitting device, to drive the first light emitting device and the second light emitting device to emit light together.

15. The display method for the display panel according to claim 13, wherein the pixel structure comprises two light emitting devices which are a first light emitting device and a second light emitting device respectively, and the first light emitting device is closer to the base substrate than the second light emitting device, and the pixel drive circuit comprises two drive sub-circuits which are a first drive sub-circuit and a second drive sub-circuit respectively; the pixel drive circuit further comprises a first switch sub-circuit and a second switch sub-circuit; the method comprises:
writing a third control signal into the first switch sub-circuit and the second switch sub-circuit, turning on a sixth transistor and a fourth transistor, writing a second control signal into a second transistor, and writing a second level signal into a first electrode of the second light emitting device, to drive the second light emitting device to emit light;
writing the third control signal into the first switch sub-circuit and the second switch sub-circuit, turning on a fifth transistor and a third transistor, writing a first control signal into the first transistor, and writing a first level signal into a first electrode of the first light emitting device and the first electrode of the second light emitting device, to drive the first light emitting device and the second light emitting device to emit light together.

16. The display method for the display panel according to claim 13, wherein the pixel structures in the display substrate in the display substrate are divided into a first pixel group and a second pixel group alternately disposed in a first direction and a third pixel group and a fourth pixel group alternately disposed in a second direction; the first pixel group comprises pixel structures of a first color and pixel structures of a second color alternately disposed in the second direction; the second pixel group comprises pixel structures of a third color disposed side by side in the second direction; the third pixel group comprises pixel structures of the first color and pixel structures of the second color alternately disposed in the first direction; the fourth pixel group comprises pixel structures of the third color disposed side by side in the first direction; the method comprises:
determining a luminous brightness value of a pixel structure of a first color, a luminous brightness value of a pixel structure of a second color, and a luminous brightness value of a pixel structure of a third color in each virtual pixel unit according to a picture to be displayed;
controlling the pixel structure of the first color, the pixel structure of the second color, and the pixel structure of the third color to emit light according to the determined luminous brightness value of the pixel structure of the first color, the determined luminous brightness value of the pixel structure of the second color, and the determined luminous brightness value of the pixel structure of the third color in each virtual pixel unit;
wherein a luminous brightness of the pixel structure of the third color in each virtual pixel unit is realized by sharing luminous brightnesses of eight pixel structures of the third color nearest thereto; a luminous brightness of each pixel structure of the third color is realized by controlling luminous brightnesses of a first light emitting device and a second light emitting device in the pixel structure.

17. A display apparatus, comprising the display panel according to claim 12.

18. The display substrate according to claim 2, wherein the pixel structures in the display substrate are divided into a first pixel group and a second pixel group alternately disposed in a first direction and a third pixel group and a fourth pixel group alternately disposed in a second direction;
the first pixel group comprises pixel structures of a first color and pixel structures of a second color alternately disposed in the second direction;
the second pixel group comprises pixel structures of a third color disposed side by side in the second direction;
the third pixel group comprises pixel structures of the first color and pixel structures of the second color alternately disposed in the first direction; and
the fourth pixel group comprises pixel structures of the third color disposed side by side in the first direction.

19. The display substrate according to claim 3, wherein the pixel structures in the display substrate are divided into a first pixel group and a second pixel group alternately disposed in a first direction and a third pixel group and a fourth pixel group alternately disposed in a second direction;
the first pixel group comprises pixel structures of a first color and pixel structures of a second color alternately disposed in the second direction;
the second pixel group comprises pixel structures of a third color disposed side by side in the second direction;
the third pixel group comprises pixel structures of the first color and pixel structures of the second color alternately disposed in the first direction; and
the fourth pixel group comprises pixel structures of the third color disposed side by side in the first direction.

20. The display substrate according to claim 4, wherein the pixel structures in the display substrate are divided into a first pixel group and a second pixel group alternately disposed in a first direction and a third pixel group and a fourth pixel group alternately disposed in a second direction;
the first pixel group comprises pixel structures of a first color and pixel structures of a second color alternately disposed in the second direction;
the second pixel group comprises pixel structures of a third color disposed side by side in the second direction;
the third pixel group comprises pixel structures of the first color and pixel structures of the second color alternately disposed in the first direction; and
the fourth pixel group comprises pixel structures of the third color disposed side by side in the first direction.
